(19) United States
(12) Patent Application Publication
(10) Pub. No.: US 2011/0073252 A1
(43) Pub. Date: Mar. 31, 2011

(54) Conductive paste and method of manufacturing printed circuit board using the same

(75) Inventors: Jun Oh Hwang, Hwaseong-si (KR); Jee Soo Mok, Yongin-si (KR); Eung Suek Lee, Suwon-si (KR)

(73) Assignee: Samsung Electro-Mechanics Co., Ltd., Suwon (KR)

(21) Appl. No.: 12/656,019

(22) Filed: Jan. 13, 2010

(30) Foreign Application Priority Data
Sep. 30, 2009 (KR) 10-2009-0093189

(51) Int. Cl. H05K 3/12; B32B 38/14; H01B 1/00; H01B 1/02

(52) U.S. Cl. 156/277; 252/500; 252/519.51; 252/520.1

(57) ABSTRACT

The present invention provides a conductive paste including: a conductive powder particle including a polymer powder and a first low melting point metal and a second low melting point metal which are sequentially provided on a surface of the polymer powder and have different melting points; and a binder mixed in the conductive powder particle, and a method of manufacturing a printed circuit board using the same.

### CROSS-REFERENCE TO RELATED APPLICATIONS

This application claims the benefit of Korean Patent Application No. 10-2009-0093189 filed with the Korea Intellectual Property Office on Sep. 30, 2009, the disclosure of which is incorporated herein by reference.

### BACKGROUND OF THE INVENTION

1. Field of the Invention

The present invention relates to a conductive paste and a method of manufacturing a printed circuit board using the same, and more particularly, to a conductive paste including two kinds of low melting point metals having different melting points, and a method of manufacturing a printed circuit board using the same.

2. Description of the Related Art

Currently, a greater number of passive elements and high density and multilayer packages are mounted on a printed circuit board (PCB) due to thickness reduction and functionalization of electronic products, and this trend will continue in the future.

Basically, the PCB plays a role of connecting various electronic components to a PCB substrate according to a circuit design of electric wiring or supporting the components. And a drilling and plating method is most widely used as a method of transmitting interlayer signals and power of a substrate. However, in case that the number of holes used for connecting the interlayer signals is increased and a thin PCB is manufactured, a method of transmitting an interlayer signal by forming a bump has a great advantage in comparison with the drilling and plating method.

A mixture of conductive powder such as Ag and an epoxy resin as a binder is mainly used as a material of a conductive paste generally used for forming the bump.

Among conventional PCB manufacturing methods, a method of manufacturing a high density PCB by forming a bump with a conductive paste made of the above material on copper foil, stacking an insulating layer passing through the bump, stacking copper foil on the insulating layer, and performing heating and pressing is used. This is called a B2it method, and by using this method, it is possible to improve manufacturing efficiency by simply forming a via for interlayer connection.

The interlayer connection using this conductive paste is formed by mechanical connection between the copper foil and Ag powder particles.

That is, in case of applying force to the copper foil with high temperature and pressure, the Ag powder are inserted along a surface profile of the copper foil. There generates a difference in movement of the Ag powder according to the degree of pressure, and contact force is affected by the amount of the binder.

However, this conventional PCB manufacturing method using the conductive paste has problems on a resistance change rate at the time of thermal shock due to the contact force between the copper foil and the bump, collapse of the bump, and an interlayer insulation distance.

That is, there is a possibility that resistance is increased and electrical connection is not formed at the time of thermal shock since the contact force between the conductive paste and the copper foil is not secured. And in case of increasing the amount of the powder to improve resistivity at the time of penetration of the insulating layer, the collapse of the bump is generated, and in case of implementing a multilayer substrate by collective stacking, it is not possible to secure the interlayer insulation distance. In order to reduce the resistivity, the amount of the powder should be increased, and in that case, on the contrary, since the bump is not easily pressed at the time of pressing, the interlayer insulation distance is increased and a bump crack may be generated due to excessive pressure.

### SUMMARY OF THE INVENTION

The present invention has been proposed in order to solve the above-described problems, and it is, therefore, an object of the present invention to provide a conductive paste and a method of manufacturing a printed circuit board using the same capable of improving contact force and electrical conductivity of a bump and securing an insulation distance by forming the bump with a conductive paste including two kinds of low melting point metals having different melting points.

In accordance with an aspect of the present invention to achieve the object, there is provided a conductive paste including: a conductive powder particle including a polymer powder and a first low melting point metal and a second low melting point metal which are sequentially provided on a surface of the polymer powder and have different melting points; and a binder mixed in the conductive powder particle.

Here, the polymer powder may be made of a thermoplastic polymer.

Further, the polymer powder may have a melting point of 180° C. to 200° C.

Further, the polymer powder may have a shape of one of a sphere, an oval, a plate, ∞, and a polyhedron.

Further, the first low melting point metal may have a melting point of 160° C. to 220° C.

Further, the first low melting point metal may be made of one of SnZn₉, SnZn₈Bi₃, and SnIn₈₋₀Ag₃₋₅Bi₀₋₅.

Further, the second low melting point metal may have a melting point lower than that of the first low melting point metal.

Further, the second low melting point metal may have a melting point of 85° C. to 150° C.

Further, the second low melting point metal may be made of one of SnBi₅₇Ag₁, SnBi₅₈, and SnIn₅₂.

Further, the binder may include an epoxy resin or a phenol resin.

In accordance with another aspect of the present invention to achieve the object, there is provided a method of manufacturing a printed circuit board including the steps of: printing a conductive paste on a first substrate, wherein the conductive paste includes a conductive powder particle having a polymer powder and a first low melting point metal and a second low melting point metal, which are sequentially provided on a surface of the polymer powder and have different melting points, and a binder mixed in the conductive powder particle; drying the conductive paste; forming an insulating layer on the first substrate through the conductive paste; and stacking and pressing a second substrate on the insulating layer.

Here, the conductive powder particle may be formed by sequentially coating the first low melting point metal and the second low melting point metal on the surface of the polymer powder.

Further, the polymer powder may be made of a thermoplastic polymer.

Further, the polymer powder may have a melting point of 180° C. to 200° C.

Further, the polymer powder may have a shape of one of a sphere, an oval, a plate, ∞, and a polyhedron.

Further, the first low melting point metal may have a melting point of 160° C. to 220° C.

Further, the first low melting point metal may be made of one of SnZn₉, SnZn₈Bi₃, and SnIn₈₋₀Ag₃₋₅Bi₀₋₅.

Further, the second low melting point metal may have a melting point lower than that of the first low melting point metal.

Further, the second low melting point metal may have a melting point of 85° C. to 150° C.

Further, the second low melting point metal may be made of one of SnBi₅₇Ag₁, SnBi₅₈, and SnIn₅₂.

Further, the first low melting point metal may have a thickness larger than that of the second low melting point metal.

Further, in the step of printing the conductive paste, the conductive paste may be printed in a conical shape.

Further, in the step of drying the conductive paste, the drying process may be performed at a melting temperature of the second low melting point metal to melt the second low melting point metal.

Further, in the step of stacking and pressing the second substrate, the press process may be performed at a melting temperature of the first low melting point metal to melt the first low melting point metal.

Further, the first substrate and the second substrate may be made of copper foil.

Further, in the step of forming the insulating layer, the insulating layer may have a thickness smaller than that of the conductive paste.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view schematically showing a conductive paste in accordance with an embodiment of the present invention;

FIG. 2 is a view showing a reaction when the conductive paste in accordance with an embodiment of the present invention is dried on a substrate;

FIG. 3 is a view showing a reaction when the conductive paste in accordance with an embodiment of the present invention is pressed on the substrate; and

FIGS. 4 to 6 are cross-sectional views showing a method of manufacturing a printed circuit board using a conductive paste in accordance with an embodiment of the present invention.

### DETAILED DESCRIPTION OF THE PREFERRED EMBODIMENTS

The functions, effects, and technical constitution of a conductive paste and a method of manufacturing a printed circuit board using the same in accordance with the present invention to achieve the object will be clearly understood from the following detailed description with reference to the accompanying drawings in which the preferable embodiments of the present invention are shown.

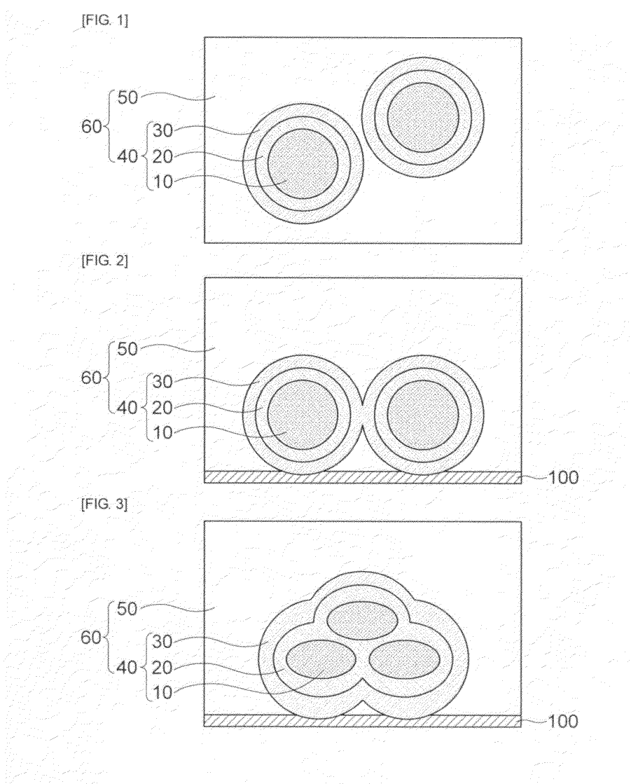

Hereinafter, a conductive paste and a method of manufacturing a printed circuit board using the same in accordance with an embodiment of the present invention will be described in detail with reference to FIGS. 1 to 6.

First, FIG. 1 is a view schematically showing a conductive paste in accordance with an embodiment of the present invention.

As shown in FIG. 1, a conductive paste 60 in accordance with an embodiment of the present invention includes a conductive powder particle 40 having a polymer powder 10 and a first low melting point metal 20 and a second low melting point metal 50, which are sequentially provided on a surface of the polymer powder 10 and have different melting points, and a binder 50 mixed in the conductive powder particle 40.

The conductive powder particle 40 is formed by sequentially coating the first low melting point metal 20 and the second low melting point metal 30 on the surface of the polymer powder 10.

A high temperature spray method and so on may be used as a coating method of the first and second low melting point metals 20 and 30.

The conductive paste 60 in accordance with an embodiment of the present invention is manufactured by uniformly mixing the binder 50 in the conductive powder particle 40 including the polymer powder 10 and the first and second low melting point metals 20 and 30 in a predetermined ratio.

Here, the polymer powder 10 is made of a thermoplastic polymer having a melting point of 180° C. to 200° C.

Further, the polymer powder 10 has a size of 0.1 μm to 5 μm and a spherical shape. The shape of the polymer powder 10 is not limited to the spherical shape, and the polymer powder 10 may have various shapes such as oval, plate, ∞, and polyhedron.

The first low melting point metal 20 coated on the surface of the polymer powder 10 is a metal having a melting point of 160° C. to 220° C.

At this time, the first low melting point metal 20 may be, for example, SnZn₉, SnZn₈Bi₃, or SnIn₈₋₀Ag₃₋₅Bi₀₋₅.

Among the above materials of the first low melting point metal 20, SnZn₉ has a melting point of 199° C., SnZn₈Bi₃ has a melting point of 191° C. to 198° C., and SnIn₈₋₀Ag₃₋₅Bi₀₋₅ has a melting point of 197° C. to 208° C.

The first low melting point metal 20 has a thickness of 0.1 μm to 10 μm.

The second low melting point metal 30 coated on a surface of the first low melting point metal 20 is a metal having a melting point lower than that of the first low melting point metal 20, that is, a metal having a melting point of 85° C. to 150° C.

The second low melting point metal 30 may be, for example, SnBi₅₇Ag₁ SnBi₅₈, or SnIn₅₂.

Among the above materials of the second low melting point metal 30, SnBi₅₇Ag₁ has a melting point of 137° C. to 139° C., SnBi₅₈ has a melting point of 138° C., and SnIn₅₂ has a melting point of 118° C.

The second low melting point metal 30 has a thickness of 0.1 μm to 10 μm.

The reason for using the first and second low melting point metals 20 and 30 having the different melting points as shown above is that drying and press process temperatures of a bump formed of the conductive paste 60 are different from each other and to optimally respond to an external temperature applied to the conductive paste 60 in the drying and press processes.

That is, the drying process of the bump is performed at a temperature of 85° C. to 150° C., which is the melting point of the second low melting point metal 30, and the press process is performed at a temperature of 160° C. to 220° C., which is the melting point of the first low melting point metal 20.

Further, it is possible to reduce material cost of the conductive powder particle 40 by using the polymer powder 10 inside the conductive powder particle 40, and it is possible to secure an interlayer insulation distance required for a substrate by applying the polymer powder 10 having the melting point of approximately 200° C.

The binder 50 mixed with the conductive powder particle 40 in which the first and second low melting point metals 20 and 30 having the different melting points are sequentially coated on the surface of the polymer powder includes an epoxy resin or a phenol resin.

A conventional conductive paste including Ag powder depends on a binder and secures electrical conductivity and contact force through mechanical junction, but the conductive paste 60 in accordance with the above-described embodiment of the present invention is a paste capable of forming an intermetallic compound as well as the binder 50.

Especially, the conductive paste 60 in accordance with an embodiment of the present invention includes two kinds of the first and second low melting point metals 20 and 30 having the different melting points, so that the second and first low melting point metals 30 and 20 and the polymer powder 10 sequentially react in the drying and press processes of the bump, thereby improving contact force and electrical conductivity of the bump and securing an insulation distance.

Next, FIG. 2 is a view showing a reaction when the conductive paste in accordance with an embodiment of the present invention is dried on a substrate, and FIG. 3 is a view showing a reaction when the conductive paste in accordance with an embodiment of the present invention is pressed on the substrate.

First, referring to FIG. 2, after the conductive paste 60 is printed on a first substrate 100 which is made of copper foil and so on, the conductive paste 60 is dried at a temperature of 85° C. to 150° C.

As the drying process is performed under the above temperature condition, the second low melting point metal 30 disposed on the outermost layer of the conductive powder particle 40 is melted to be combined with the adjacent second low melting point metal 30, and the binder 50 is partially cured.

And the first substrate 100, which is made of copper foil and so on, and the second low melting point metal 30 are combined with each other, so that it is possible to secure contact force between the first substrate 100 and the conductive powder particle 40 and improve electrical conductivity.

As the drying process is finished, an intermetallic compound having strong bonding force is formed through mutual combination between the adjacent second low melting point metals 30 as well as hardness generated by the partially cured binder 50, thereby obtaining the bump having high hardness.

Next, referring to FIG. 3, the conductive paste 60 passing through the drying process is pressed at a temperature of 160° C. to 200° C.

As the press process is performed, the first low melting point metal 20 is melted to be combined with the adjacent first low melting point metal 20, and the polymer powder 10 inside the first low melting point metal 20 is also melted to secure an optimal interlayer distance. At this time, the polymer powder 10 is an insulating material, and thus it is possible to secure an insulation distance even though the bump is lowered to a desired height. Therefore, it is possible to collectively stack the substrates.

The first and second low melting point metals 20 and 30 before reaction are completely melted at a temperature near the melting point, but they show completely different phases after reaction and are not easily melted even at a high temperature.

FIGS. 4 to 6 are cross-sectional views showing a method of manufacturing a printed circuit board using a conductive paste in accordance with an embodiment of the present invention.

A method of manufacturing a printed circuit board using a conductive paste in accordance with an embodiment of the present invention, first, as shown in FIG. 4, forms a conical bump by printing a conductive plate 60 on a first substrate 100.

The first substrate 100 is made of copper foil and so on.

The conductive paste 60 includes a conductive powder particle 40 having a polymer powder 10 and a first low melting point metal 20 and a second low melting point metal 30, which are sequentially provided on a surface of the polymer powder 10 and have different melting points, and a binder 50 mixed in the conductive powder particle 40.

The conductive powder particle 40 is formed by sequentially coating the first low melting point metal 20 and the second low melting point metal 30 on the surface of the polymer powder 10.

A high temperature spray method and so on may be used as a coating method of the first and second low melting point metals 20 and 30.

The conductive paste 60 in accordance with an embodiment of the present invention is manufactured by uniformly mixing the binder 50 in the conductive powder particle 40 including the polymer powder 10 and the first and second low melting point metals 20 and 30. The binder 50 includes an epoxy resin or a phenol resin.

The polymer powder 10 is made of a thermoplastic polymer having a melting point of 180° C. to 200° C.

Further, the polymer powder 10 has a size of 0.1 μm to 5 μm and a spherical shape. The shape of the polymer powder 10 is not limited to the spherical shape, and the polymer powder 10 may have various shapes such as oval, plate, ∞, and polyhedron.

The first low melting point metal 20 coated on the surface of the polymer powder 10 is a metal having a melting point of 160° C. to 220° C.

At this time, the first low melting point metal 20 may be, for example, SnZn₉, SnZn₈Bi₃, or SnIn₈₋₀Ag₃₋₅Bi₀₋₅.

Among the above materials of the first low melting point metal 20, SnZn₉ has a melting point of 199° C., SnZn₈Bi₃ has a melting point of 191° C. to 198° C., and SnIn₈₋₀Ag₃₋₈Bi₀₋₅ has a melting point of 197° C. to 208° C.

The first low melting point metal 20 has a thickness of 0.1 μm to 10 μm.

The second low melting point metal 30 coated on a surface of the first low melting point metal 20 is a metal having a melting point lower than that of the first low melting point metal 20, that is, a metal having a melting point of 85° C. to 150° C.

The second low melting point metal 30 may be, for example, SnBi₅₇Ag₁, SnBi₅₈, or SnIn₅₂.

Among the above materials of the second low melting point metal 30, SnBi₅₇Ag₁ has a melting point of 137° C. to 139° C., SnBi₅₈ has a melting point of 138° C., and SnIn₅₂ has a melting point of 118° C.

The second low melting point metal 30 has a thickness of 0.1 μm to 10 μm.

Then, the conductive paste 60 is dried to give hardness to the bump. The drying process of the conductive paste 60 is performed at a temperature of 85° C. to 150° C., which is the melting point of the second low melting point metal 30.

As the drying process is performed under the above temperature condition, the second low melting point metal 30 disposed on the outermost layer of the conductive powder particle 40 is melted to be combined with the adjacent second low melting point metal 30, and the binder 50 is partially cured.

And the first substrate 100, which is made of copper foil and so on, and the second low melting point metal 30 are combined with each other, so that it is possible to secure contact force between the first substrate 100 and the conductive powder particle 40 and improve electrical conductivity.

As the drying process is finished, an intermetallic compound having strong bonding force is formed through mutual combination between the adjacent second low melting point metals 30 as well as hardness generated by the partially cured binder 50, thereby obtaining the bump having high hardness.

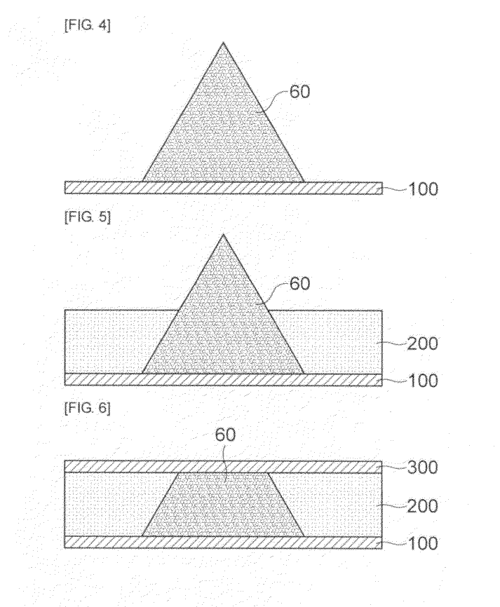

Next, as shown in FIG. 5, an insulating layer 200 is formed on the first substrate 100 through the conductive paste 60. The insulating layer 200 is a means for implementing interlayer electrical insulation, for example, prepreg. The insulating layer 200 has a thickness smaller than that of the conductive paste 60.

At this time, since the hardness of the bump is improved by the intermetallic compound formed by the combination between the second low melting point metals 30 as well as the cured binder 50, there is an advantage that the insulating layer 200 easily passes through the conductive paste 60.

Meanwhile, if the melting points of the first and second low melting point metals 20 and 30 are the same, the insulating layer 200 may not easily pass through the conductive paste 60 since the height of the bump is dramatically reduced due to the metal melted in the drying process. Therefore, the melting points of the first and second low melting point metals 20 and 30 should be different, and it is advantageous that a coating thickness of the first low melting point metal 20 is larger than that of the second low melting point metal 30.

After that, as shown in FIG. 6, a second substrate 300 is stacked and pressed on the insulating layer 200. The second substrate 300 is made of copper foil and so on, like the first substrate 100.

The press process is performed at a temperature of 160° C. to 200° C., which is the melting point of the first low melting point metal 20. Accordingly, the first low melting point metal 20 is melted to be combined with the first low melting point metal 20. At this time, the polymer powder 10 inside the first low melting point metal 20 is also melted to secure an optimal interlayer distance.

The polymer powder 10 is an insulating material, and thus it is possible to secure an insulation distance even though the bump is lowered to a desired height. Therefore, it is possible to collectively stack the substrates.

Further, since the contact force between the first substrate 100 and the conductive powder particle 40 is further improved in the press process, it is possible to further improve electrical characteristics.

Then, although it is not shown in the drawings, in case of a double-sided substrate, after forming a circuit pattern by patterning the first and second substrates 100 and 300, processes of forming PSR and a gold plating layer may be performed on the circuit pattern.

Further, in case of a multilayer substrate, after forming a circuit pattern by patterning the second substrate 300, processes of printing the conductive paste 60 on the circuit pattern and stacking the insulating layer 200 may be repeated.

As described above, according to the conductive paste and the method of manufacturing the printed circuit board using the same in accordance with the present invention, by forming the bump using the conductive paste in which the first and second low melting point metals having the different melting points are sequentially coated on the surface of the polymer powder, the second and first low melting point metals and the polymer powder sequentially react in the drying and press processes of the bump, so that it is possible to improve the contact force and electrical conductivity of the bump and secure the interlayer insulation distance.

Further, since the intermetallic compound is formed inside the conductive paste of the present invention, it is possible to obtain the bump having high hardness, and due to this, there is an advantage that the insulating layer easily passes through the bump.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A conductive paste comprising:
a conductive powder particle including a polymer powder and a first low melting point metal and a second low melting point metal which are sequentially provided on a surface of the polymer powder and have different melting points; and
a binder mixed in the conductive powder particle.

2. The conductive paste according to claim 1, wherein the polymer powder is made of a thermoplastic polymer.

3. The conductive paste according to claim 2, wherein the polymer powder has a melting point of 180° C. to 200° C.

4. The conductive paste according to claim 1, wherein the polymer powder has a shape of one of a sphere, an oval, a plate, ∞, and a polyhedron.

5. The conductive paste according to claim 1, wherein the first low melting point metal has a melting point of 160° C. to 220° C.

6. The conductive paste according to claim 5, wherein the first low melting point metal is made of one of SnZn₉, SnZn₈Bi₃, and SnIn₈₋₀Ag₃₋₅Bi₀₋₅.

7. The conductive paste according to claim 1, wherein the second low melting point metal has a melting point lower than that of the first low melting point metal.

8. The conductive paste according to claim 7, wherein the second low melting point metal has a melting point of 85° C. to 150° C.

9. The conductive paste according to claim 8, wherein the second low melting point metal is made of one of SnBi₅₇Ag₁, SnBi₅₈, and SnIn₅₂.

10. The conductive paste according to claim 1, wherein the binder includes an epoxy resin or a phenol resin.

11. A method of manufacturing a printed circuit board comprising:
printing a conductive paste on a first substrate, wherein the conductive paste includes a conductive powder particle having a polymer powder and a first low melting point metal and a second low melting point metal, which are sequentially provided on a surface of the polymer powder and have different melting points, and a binder mixed in the conductive powder particle;
drying the conductive paste;
forming an insulating layer on the first substrate through the conductive paste; and
stacking and pressing a second substrate on the insulating layer.

12. The method according to claim 11, wherein the conductive powder particle is formed by sequentially coating the first low melting point metal and the second low melting point metal on the surface of the polymer powder.

13. The method according to claim 11, wherein the polymer powder is made of a thermoplastic polymer.

14. The method according to claim 11, wherein the polymer powder has a melting point of 180° C. to 200° C.

15. The method according to claim 11, wherein the polymer powder has a shape of one of a sphere, an oval, a plate, ∞, and a polyhedron.

16. The method according to claim 11, wherein the first low melting point metal has a melting point of 160° C. to 220° C.

17. The method according to claim 16, wherein the first low melting point metal is made of one of SnZn₉, SnZn₈Bi₃, and SnIn₈₋₀Ag₃₋₅Bi₀₋₅.

18. The method according to claim 11, wherein the second low melting point metal has a melting point lower than that of the first low melting point metal.

19. The method according to claim 18, wherein the second low melting point metal has a melting point of 85° C. to 150° C.

20. The method according to claim 19, wherein the second low melting point metal is made of one of SnBi₅₇Ag₁, SnBi₅₈, and SnIn₅₂.

21. The method according to claim 11, wherein the first low melting point metal has a thickness larger than that of the first low melting point metal.

22. The method according to claim 11, wherein in printing the conductive paste, the conductive paste is printed in a conical shape.

23. The method according to claim 11, wherein in drying the conductive paste, the drying process is performed at a melting temperature of the second low melting point metal to melt the second low melting point metal.

24. The method according to claim 11, wherein in stacking and pressing the second substrate, the press process is performed at a melting temperature of the first low melting point metal to melt the first low melting point metal.

25. The method according to claim 11, wherein the first substrate and the second substrate are made of copper foil.

26. The method according to claim 11, wherein in forming the insulating layer, the insulating layer has a thickness smaller than that of the conductive paste.
